(19) United States
(12) Patent Application Publication
(10) Pub. No.: US 2017/0279406 A1
(43) Pub. Date: Sep. 28, 2017

(54) High Efficiency Hybrid Solar Energy Device

(71) Applicant: 510nano, Inc., Durham, NC (US)

(72) Inventors: Reginald Parker, Durham, NC (US); Marcus Shute, Conyers, GA (US); Frederick J. Foreman, Douglasville, GA (US)

(21) Appl. No.: 15/480,622

(22) Filed: Apr. 6, 2017

Related U.S. Application Data
(63) Continuation-in-part of application No. 13/019,021, filed on Feb. 1, 2011, now abandoned.

(51) Int. Cl. H02S 40/22; H01L 31/0304; H01L 31/054; H02S 40/44; H02S 20/32

(52) U.S. Cl. CPC H02S 40/22; H02S 40/44; H02S 20/32; H01L 31/0549; H01L 31/0543; H01L 31/0304

(57) ABSTRACT

An apparatus for generating electricity with the ability to distill a liquid and/or expand a working fluid and/or produce mechanical energy and/or produce thermal energy and/or produce chemical transformations through separately utilizing light in the infrared (IR) region and light within the visible and ultraviolet (UV) regions. The apparatus uses methods to capture diffuse and direct polychromatic light, concentration and multiplication of that light up to 1000 times or more, collimation of light, separation of the spectrum into the IR and UV/visible bands, generation of electricity through conversion of at least UV/visible light, and useful conversion of infrared light into applications to generate a distilled liquid or compound, expand a working fluid, produce mechanical energy, produce thermal energy, produce chemical energy and/or generate additional electricity. Non-reflected radiant energy may be used to operate a suitable photovoltaic cell or stack of cells. In alternative embodiments, the spectral separator may reflect most radiant energy incident upon it to one or more photovoltaic cells and pass infrared to an accumulator for use as heat energy to generate mechanical or chemical energy or generate further electrical energy.

This application is a continuation-in-part of U.S. patent application Ser. No. 13/019,021 filed Feb. 1, 2011, and the '021 application claims the benefit of priority to U.S. Provisional Application Ser. No. 61/301,030 filed Feb. 3, 2010, the entire subject matter of both patent applications being incorporated by reference herein in their entirety.

### TECHNICAL FIELD

This invention generally relates to the technical field of solar energy conversion apparatus and, more particularly, to an apparatus for efficiently using solar radiation for generating electricity, distilling liquids, expanding working fluids, generating mechanical energy, reacting chemicals and/or producing thermal energy in the form of a hybrid solar energy device which utilizes the infrared energy spectrum as well as the rest of the visible and infrared solar energy spectrum including the ultraviolet.

### BACKGROUND

The following discussion of the solar energy arts should not be construed as an admission that the subject matter of the discussion is known to others.

Bright sunlight is known to provide an irradiance of just over 1 kilowatt per square meter at sea level. Of this energy on average, 527 watts power is infrared radiation; 445 watts is visible light; and 32 watts is ultraviolet radiation. The visible light energy including the ultraviolet band through the infrared band is received primarily as panchromatic light at approximately equivalent level across the spectrum from ultraviolet through the visible and including the infrared spectra. The majority of heat in thermal radiation is found in the infrared spectra.

Solar radiation is derived from direct, diffuse and/or reflected radiation. The majority of light emanates from either direct or diffuse light. At solar noon and with a clear sky, approximately 84.5% is direct light. However, when the sun is at 10 degrees above the horizon, the percent of diffuse radiation can reach 40%. Additionally, atmospheric conditions like clouds and pollution will have an increased percentage of diffuse radiation. On an extremely overcast day, the vast majority of the solar radiation will be diffuse radiation. Generally speaking, the larger the percentage of diffuse radiation, the less the total insulation and the lower access to direct light. Light hitting surfaces reflects light and adds to the total insolation. Asphalt can reflect as much as 4% of the light that strikes it, whereas a lawn can reflect up to 25% and snow can reflect up to 90% of the radiation striking it.

Typically, solar panels receive solar radiation and pass the energy to photovoltaic cells which convert up to 18% of the received energy into electric energy for mono-crystalline silicon based solar panels which electric energy may be used in the world's power grid. For high concentrated photovoltaic and concentrated solar thermal technologies, almost 100% of energy received is direct which is lower than total insolation. Further, these technologies convert up to 28% of the direct light into electricity or up to 23.8% of the total insolation. Therefore, concentrated technologies can have a 24% advantage on conventional photovoltaic (PV) on clear days. However, on days when diffuse radiation is significant, the advantage is lost and thereby can render concentrated technology economically unfavorable.

Efficient and strategic concentration, collimation, separation, collection and conversion of solar radiation is useful in a number of applications. Solar radiation is of particular value for devices that convert solar energy to various energy forms and is useful in the delivery of various distilled liquids with a boiling point up to 740° F. or higher. Known concentrator technology can multiply the sun's energy at two times the sun's energy or lower and as much as one hundred times the sun's energy or significantly more. Concentrator technology is achieved by focusing the sun's power onto a smaller platform. As an example, a ten inch by ten inch Fresnel lens can focus the sun's energy onto a one inch by one inch surface concentrating the sun's energy. In doing so, the surface will experience the power of one hundred times the power of the sun (or one hundred suns). Other lens and concentrating systems are known and may be considered similar devices such as magnifying lens systems comprising multiple lenses at predetermined focal lengths from one another and the like known by their power of magnification.

Applications for radiation concentrator technology may be for concentrated photovoltaic technology (CPV) or for concentrated solar thermal (CST) technology. CPV uses the concentrated light onto a solar cell, for example, a known photovoltaic cell. An increase in solar radiation increases the production of photocurrent by the cell; however, there is a concurrent decrease in overall power due to the addition of heat found in IR energy which may be lost in the light to electric conversion process, as well as losses due to optical inefficiencies. CST, on the other hand, for example, may heat a working fluid which either directly or indirectly drives a turbine producing electricity and/or utility scale steam. The majority of the heating of the working fluid is derived from the IR portion of the spectrum. Thus, CPV and CST in combination are promising technologies requiring further development; however, as discussed above, infrared (IR) light reduces the efficiency of CPV, and visible light is ineffectual in CST.

Large-scale light concentrators for obtaining solar energy typically include a set of opposed, curved mirrors, with a Cassegrain arrangement, as an optical system for concentrating light onto a receiver that is positioned at a focal point. A few examples employing the Cassegrain model are U.S. Pat. No. 5,979,438 (Nakamura) and U.S. Pat. No. 5,005,958 (Winston et al.) incorporated by reference herein in their entirety. U.S. Pat. No. 6,530,369 (Yogev et al.) describes a solar concentration system comprising a system of first reflectors for concentrating toward a second reflector for focusing light at a solar conversion device. U.S. Pat. No. 7,669,593 (Blackmon, Jr. et al.) discloses a concentration tower having a plurality of reflectors for directing radiant energy at a reflector mounted at the top of a tower.

A more recent development may provide a more compact collection apparatus, planar concentrators. Planar concentrators similarly employ primary and secondary curved mirrors with a Cassegrain arrangement, separated by a dielectric optical material, for providing high light flux concentration.

Other examples of light concentrators include the use of a Fresnel lens as an optical system for concentrating light onto a receiver that is positioned at a focal point. A few examples employing the Fresnel model are U.S. Pat. No. 4,069,812 (O'Neill), U.S. Pat. No. 4,088,120 (Anderson) and U.S. Pat. No. 6,399,874 (Olah).

Some types of solar energy systems operate by converting light energy to heat. In various types of flat plate collectors and solar concentrators, concentrated sunlight heats a fluid traveling through the solar cell to high temperatures for power generation. An alternative type of solar conversion mechanism, more adaptable for use in thin panels and more compact devices, may use photovoltaic (PV) materials to convert sunlight directly into electrical energy.

As is well known, sunlight is polychromatic. Sunlight contains broadly distributed spectral content at all frequencies, ranging, for example, from ultraviolet (UV), through visible, and infrared (IR) wavelengths, each wavelength having an associated energy level, typically expressed in terms of electron-volts (eV). Due to differing band-gap characteristics between materials, the response of any one particular photovoltaic material depends upon the incident wavelength. Photons having an energy level below the band gap of a material slip through the material. For example, it is to be noted that red light photons (nominally around 1.9 eV) are not absorbed by high band-gap semiconductors and energy from violet light photons (nominally around 3 eV) is wasted as heat in a low band-gap semiconductor.

One strategy for obtaining higher efficiencies from photovoltaic materials is to form a stacked photovoltaic cell, also sometimes termed a multi-function photovoltaic device. These devices are formed by stacking multiple photovoltaic cells on top of each other. With such a design, each successive photovoltaic cell in the stack, with respect to the incident light source, has a lower band-gap energy due to the depth of the stack. In a simple stacked photovoltaic device, for example, an upper photovoltaic cell, consisting of gallium arsenide (GaAs), captures the higher energy of blue light. A second cell in the stack, of gallium antimonide (GaSb), converts the lower energy infrared light into electricity. One example of a stacked photovoltaic device is given in U.S. Pat. No. 6,835,888 entitled “Stacked Photovoltaic Device” to Sano et al., incorporated by reference herein in its entirety.

While stacked photovoltaic devices can provide some measure of improvement in overall efficiency, these multi-layered devices can be costly to fabricate. There can also be restrictions on the types of materials that can be stacked together on top of each other, making it difficult for such an approach to prove economical for a broad range of applications. Further, when these devices are stacked, the currents are required to be matched and are thusly matched to the lowest current generated on the stack, thereby limiting any excess current production from the other materials in the stack. As a consequence, stacked photovoltaic devices are not able to achieve their highest potential efficiencies. Another approach is to separate the light according to wavelength into two or more different spectral portions, and to concentrate each portion onto an appropriate photovoltaic receiver device, with two or more photovoltaic receivers arranged side by side. With this approach, photovoltaic device fabrication is simpler and less costly, and a wider variety of semiconductors can be considered for use. This type of solution requires supporting optics for both separating light into suitable spectral components and concentrating each spectral component onto its corresponding photovoltaic surface and, in some cases, collimating diffuse light. However, losses are seen in separating the light due to optical inefficiencies. The goal of splitting light however, is to have lower losses due to optical inefficiencies than the inefficiencies derived in the stack photovoltaic device strategy.

One proposed solution for simultaneously separating and concentrating light at sufficient intensity is described in a paper entitled “New Cassegrainian PV Module using Dichroic Secondary and Multijunction Solar Cells” presented at an International Conference on Solar Concentration for the Generation of Electricity or Hydrogen in May, 2005 by L. Fraas, J. Avery, H. Huang, and E. Shifman (hereinafter, Fraas et al.). In the module described, a curved primary mirror collects light and directs this light toward a dichroic hyperbolic secondary mirror, near the focal plane of the primary mirror. IR light is concentrated at a first photovoltaic receiver near the focal point of the primary mirror. The secondary mirror redirects near-visible light to a second photovoltaic receiver positioned near a vertex of the primary mirror. In this way, each photovoltaic receiver obtains the light energy for which it is optimized, increasing the overall efficiency of the solar cell system. A further dichroic system incorporating a Cassegrain solution is described by U.S. Pat. No. 7,741,557 (Cobb et al.) which discusses the separation of first and second spectral bands for transmission to first and second planar surfaces. The light of the first and second spectral bands are received at first and second photovoltaic cells.

While the approach described by Fraas et al. advantageously provides spectral separation and concentrates light using the same set of optical components, there are some significant limitations to the solution that it presents. A first problem relates to the overall losses due to obstruction, as were noted earlier. As another problem, the apparatus described by Fraas et al. has a limited field of view of the sky because it has a high concentration in each axis due to its rotational symmetry. Yet another drawback relates to the wide bandwidths of visible light provided to a single photovoltaic receiver. With many types of photovoltaic materials commonly used for visible light, an appreciable amount of the light energy would still be wasted using such an approach, possibly causing excessive heat. Yet another drawback is its inability to effectively use diffuse light to generate electricity as some diffuse light is rejected due to its angle of entry.

Dichroic surfaces are used for the hyperbolic mirror in the solution proposed by, for example, Fraas et al., to provide spectral separation of light using interference effects obtained from coatings formed from multiple overlaid layers having different indices of refraction and other characteristics. In operation, dichroic coatings may reflect and transmit light as a function of incident angle and wavelength. As the incident angle varies, the wavelength of light that is transmitted or reflected by a dichroic surface also changes. Where a dichroic coating is used with incident light at angles beyond about +/−20 degrees from normal, undesirable spectral effects can occur, so that spectral separation of light, due to wavelength differences, is compromised at such higher angles.

There have been a number of light collector solutions employing dichroic surfaces for spectral splitting. For example, in an article entitled “Spectral Beam Splitting Technology for Increased Conversion Efficiency in Solar Concentrating Systems: A Review”, available online at www.sciencedirect.com, authors A. G. Imenes and D. R. Mills provide a survey of solar collection systems, including some using dichroic surfaces. For example, the description of a tower reflector (FIG. 24 in the Imenes and Mills article) shows one proposed solution that employs a curved dichroic beamsplitter as part of the optics collection system. High incident angles of some portion of the light on this surface could render such a solution as less than satisfactory with respect to light efficiency. Similarly, U.S. Pat. No. 4,700,013 entitled “Hybrid Solar Energy Generating System” to Soule describes the use of a dichroic surface as a selective heat mirror, incorporated by reference in its entirety. Soule' s architecture includes a concentrator, a plano-concave lens, a heat mirror, one solar cell requiring cooling and a heat absorber for alleviating PV cell circuitry due to sun magnification. Soule is limited to 40× magnification power. Without the cooling (heat absorber), there is a danger that the solar cell will fail due to the heat generated by forty suns, especially heat energy from the IR band. Further, Soule found that poor management of the optics and of the heat management system will cause damage of the circuit card assembly and the associated microelectronics and solar implements.

There are inherent problems with dichroic surface shape and placement for light focused from a parabolic mirror. A flat dichroic surface positioned near the focal region of a parabolic reflector would exhibit poor separation performance for many designs, constraining the dimensions of a light collection system. A properly curved dichroic surface, such as a hyperbolic curved surface, can be positioned at or near the focal region, but may obstruct some portion of the available light, as noted earlier.

Conventional approaches for light concentration have been primarily directed to rotationally symmetrical optical systems using large-scale components. However, this approach may not yield satisfactory solutions for smaller solar panel devices. There exists a need for an anamorphic light concentrator that can be formed on a transparent body and fabricated in a range of sizes, where the light concentrator design allows it to be extended in a direction orthogonal to the direction of its highest optical power, whether extended linearly or extended along a curve.

Against obstacles such as poor dichroic surface response, conventional approaches have provided only a limited number of solutions for achieving, at the same time, both good spectral separation and efficient light flux concentration of each spectral component. The Fresnel model may be used to remove those issues. A flat dichroic surface may be used to separate light to allow for efficient separation. Use of collimation will provide more efficient use of technologies such as a Fresnel lens and flat dichroic surfaces. Further use of solar thermal applications allow for generation of thermal, mechanical, chemical and/or electrical energy, as well as expansion of a working fluid, storage of energy through production of Hydrogen, remediation of polluting streams, and/or generation of potable water. Further use of thermal applications can lower the overall heat load to the system. In doing so, the impact of the efficiency of the solar cell converting ultraviolet and visible light into electricity can be increased.

A problem faced, for example, by satellites, is the focusing of radiant energy when the satellite is forever moving in relation to the sun. U.S. Pat. No. 6,557,804 (Carroll) suggests using two synchronized motors to continuously point a solar panel at the sun as the satellite moves through the sky.

A heat accumulator may be used with solar panels to collect, preserve and transfer heat. Known heat accumulators are described, for example, by U.S. Pat. No. 3,845,625 (Schroder); U.S. Pat. No. 4,434,785 (Knudsen); and U.S. Pat. No. 4,714,821 (Jacobsson). For example, the electric heating coils 19 of the '821 patent may be replaced with infrared energy absorbent material.

US 2009/0025783 (Wernham et al.) describes an optical filter, which is none of the following, a dichroic lens, hot or cold. The Wernham filter allegedly absorbs a portion of received light and allows the remaining energy to pass through. There is some confusion where [004] states a filter absorbs and reflects (does not pass) while the second sentence states that energy is allowed to pass through.

US2010/0218804 (Shin et al.) describes an algorithm that controls a structure to align a concentrator with solar cells at [004]. Shin specifies the use of a collimator 22 as a concentrator (FIG. 1). Shin also suggests a Fresnel lens as does Soule.

U.S. Pat. No. 6,302,100 (Vandenberg) comprises a collimator having a glass top and a plastic bottom. This combination allegedly allows utility against weather and achieve low cost. Vandenberg further achieves concentration by means of a funnel and waveguide for the specific purpose of heat production. However, due to the use of a plastic bottom, the combination is limited not to exceed temperatures of 200° C. so as to not melt the plastic or for the plastic to lose cohesion with the glass top. Therefore, the combination limits systems to low concentrations in the range of 40×.

US2010/0170560 (Sapienza et al.) discloses as allegedly durable, lightweight and efficient solar concentrator. A concave shaped array of square reflector panels reflect received sunlight for reception by a device 16 which then coverts the collected sunlight.

US 2005/0051208 (Mount) discloses a system for transferring heat in a thermoelectric generator system. A Fresnel lens 103 (FIG. 1A) passes light to reflector walls and a heat generator 106 collects usable heat for a variety of purposes.

These prior art technologies suggest that there is an opportunity to improve the efficiency of solar to electrical energy conversion and other forms of energy conversion from, for example, typical solar energy conversion efficiency rates of approximately 18% for mono-crystalline silicon solar cells by a factor of at least two while decreasing the failure rate of PV cells if high temperature solar energy is allowed to damage a solar cell by focusing the energy of the sun at high multiplication factors on a small solar cell integrated circuit.

### SUMMARY OF THE EMBODIMENTS

It is an object of embodiments of the present invention to advance the art of light collimation and collection as well as spectral separation for energy collection. A further object is to reduce the levelized cost of solar energy while, at the same time, improving efficiency and reducing a failure rate of solar PV integrated circuit cells due to solar concentration and resultant potentially damaging heat. In one embodiment, the levelized cost of solar energy is 80% lower than conventional PV systems on an unsubsidized basis, below grid costs of seven to twelve cents (U.S.) per kWh.

In summary, light from a point source, the sun, and scattered light, for example, on a cloudy day, are captured, concentrated, collimated and constructively converted such that approximately 50% or more of visible and invisible (infrared and ultraviolet) light may be converted into electricity or other useful energy. With this object in mind, the present invention provides a number of embodiments of apparatus for obtaining solar radiation from a polychromatic radiant energy source, the apparatus comprising: a) one or more concentrators, b) one or more collimators, c) one or more spectral separators, d) one or more ultraviolet/visible photovoltaic devices manufactured by Spectrolab, a subsidiary of Boeing, operating in the UV/visible and/or the infrared spectral range made either by Envoltek, a licensee of Boeing or Galaxy Wafer, a subsidiary of IQE plc and e) an heat (IR) collector or accumulator manufactured, for example, by Johnson R&D. In summary, a visible and UV solar cell may be an integrated circuit photovoltaic solar cell manufactured by Spectrolab, a subsidiary of Boeing. An infrared solar cell may be an integrated circuit photovoltaic solar cell manufactured by Galaxy Wafer. The heat collector or accumulator can be a heat to electricity device, a heat accumulator and/or a motor that uses an expanding working fluid (e.g. a steam generator, a hydraulic motor, or an air turbine) and/or a reacting medium (e.g. high temperature electrolysis, endothermic reactions or polymerizations). Additionally, use of a steam generator allows for generation of potable water and utility grade steam.

Simultaneous heat and optical management is required within the preferred embodiment in order to achieve the most efficient conversion. Firstly, the use of collimation presents the spectrum uniformly in both intensity and by color. That is, there are no hot spots or the distribution of wavelengths is not distorted from the original spectral distribution. This ensures that the operating solar cells will not be overexposed and will not succumb to formation of moieties due to variation in colors. Secondly, spectral splitting allows for a reduction of overall inefficiency. The visible photovoltaic device receives only visible light which is converted into electricity at greater than 50% efficiency. The remaining light is either reflected, refracted, or transformed into heat. The amount transformed into heat is substantially lower than it would be if Infrared was not split off. The Al monoblock housing the chip will efficiently radiate off the absorbed heat which maintains high conversion efficiency at this chip. Further, the infrared photovoltaic device converts up to 30% or more infrared into electricity, also reduced the overall heat content and in this case improves the overall efficiency of the system. Again, use of the Al monoblock helps to efficiency radiate excess thermal energy. By effectively managing the optics and heat, the system is able to achieve high efficiency at a substantially low cost.

It is an aspect of the embodiment that an apparatus collimates diffuse or scattered light into nearly normal light while not interfering with direct light from the sun. The diffuse light becomes nearly normal enough that the need to tilt flat panels is lessened (although a tilting motor may be used in a first axis) and the need to use one axis and two axis trackers (the second axis for following the point source sun light across the sky between sunrise and sunset) for concentrated solar technologies is useful and improves conversion efficiency of a hybrid system. The total useful solar radiation for both standard solar collectors and concentrated solar technologies may be improved.

It is another aspect of the embodiments that an apparatus provides concentration of light with its subsequent spectral separation into at least two spectral bands, and energy conversion onto two separate collectors. One collector directly produces electrical energy through conversion of visible and UV light bands into electricity, and the other collector is able to convert IR light bands into various energy forms including electricity.

It is another aspect of the embodiments that an apparatus produce potable water and utility grade steam.

It is a further aspect that embodiments of the apparatus provide an efficient mechanism for separating and concentrating radiant energy onto a photoreceiver.

Additionally, it is an aspect of the embodiments that associated apparatus reduces losses from obstruction, common to systems using the Cassegrain model.

According to one embodiment, an optional, but preferred, collimator is used to collect and channel received diffuse radiant energy to a first converging Fresnel lens. The collimator may collect light energy, for example, as the sun crosses the sky. If the Fresnel lens is used alone without a collimator, the Fresnel lens and other elements described below may be moved so as to follow the path of the sun across the sky by a programmed motor for simultaneous rotation and tilt following the solar calendar. In the northern hemisphere, the sun is highest in the sky on June 21 and lowest on December 21, and in the southern hemisphere, the opposite. A GPS location finder may be used to determine the position of a solar panel system to be installed according to the present invention and the result used to program a motor system for two axis tracking. The converging Fresnel lens, in turn, passes incident radiant energy, for example, to a diverging Fresnel lens which passes energy to a spectrum separator, for example, a dichroic lens. A domed Fresnel lens has been developed, the dome having a circular footprint on an otherwise flat Fresnel lens surface contributing to uniformly distributing collected light from the sun and scattered light collected by the collimator evenly over respective surfaces of an IR photovoltaic integrated circuit (chip) so as not to damage the chip or other circuit components due to excessive heat from magnification. The domed lens which will be discussed further herein may deliver one and a half to two times the power to a detector, IR or visible light and UV. One thousand suns of light or IR or greater may be uniformly distributed in a desirable circular, uniform pattern over a PV circular or square chip collector surface (while a flat lens creates a pattern that is not evenly distributed over the cell surface and can cause failure of circuit components). The dichroic lens may reflect the infrared energy incident on the dichroic lens via a further converging Fresnel lens to an accumulator which, for example, may collect heat energy and transfer the energy for use as chemical energy or mechanical energy. Meanwhile, the spectrum separator may pass all other bands of radiant energy via yet another Fresnel lens to a UV/visible photovoltaic cell for generation of electrical energy. In a further embodiment, the collimator, separator and Fresnel lens systems may be formed as an array for reflecting all incident infrared heat energy to a single, central accumulator. In this manner, up to 60% energy efficiency is achieved between incident radiant energy and useful energy output.

According to another embodiment, an apparatus may transform larger chemical compounds into the molecular or elemental form. For example, the apparatus can be used to transform water into molecular hydrogen and molecular oxygen or hydrocarbon outputs into molecular hydrogen and molecular carbon. In doing so, remediation of polluting streams or point sources can be achieved, as well as production of molecular Hydrogen as a means of storing potential energy.

Further, according to another embodiment, an apparatus may transform chemical compounds into molecular or elemental form allowing the remediation of polluting streams, such as flue gases containing carbon dioxide, to produce higher hydrocarbons and precursors to fuel. According to yet another embodiment, the use of one or more collimators can be used before or after a range of one or more concentrator technologies can be used to form an apparatus for the generation of various forms of useful energy.

These and other features of the embodiments will be described with reference to the drawings of which the following is a brief description.

### BRIEF DESCRIPTION OF THE DRAWINGS

FIG. 1 provides an overall system diagram showing a first embodiment of a radiant energy concentrator system including a spectral separator.

FIG. 2 provides an enlarged diagram of light devices including the spectral separator of FIG. 1.

FIG. 3(A)-(B) provide alternative embodiments of light devices including a collimator and Fresnel lens systems for separating received radiant energy into bands for electrical, chemical and mechanical energy generation.

FIG. 4(A) shows a perspective view of an exemplary array of 2 by 2 Fresnel lens systems for delivering a first visible light band to respective photovoltaic cells and dichroic lenses for transmitting infrared light as heat to a central collector column of heat for delivery to various mechanical and chemical systems as will be further discussed herein; FIG. 4(B) shows a side view of the embodiment of FIG. 4(A) and FIG. 4(C) shows a bottom view of the embodiment of FIG. 4(A).

FIG. 5 in table and schematic form shows what may be referred to herein as the Five C's or principles of operation of a preferred embodiment of a hybrid solar concentrator, namely, Capture, Concentrate, Collimate and Constructively Convert and more to show new domed lens and components taken from what Parker has recently sent. A domed concentrator Fresnel Lens receives diffuse and point source sun light and focuses the received light, for example, on to a spectral separator for focusing on a UV/visible PV cell and an IR p/n junction cell.

FIGS. 6 through 11 provide a step-by-step process of constructing a high efficiency hybrid solar concentrator. The structure described simultaneous manages both heat and optics to achieve the most efficient conversion. Collimation is used to uniformly apply both intensity and color to reduce hot spots and structural moieties. Also, spectral reduces heat generation on from visible and infrared on both photovoltaic devices, thus reducing the heat load required to manage. Lastly, use of the Al monoblock with heat fins easily radiates any excess heat from the system which produces a high efficiency, low cost solar technology.

FIG. 6 shows in perspective view a domed Fresnel lens for capturing direct sunlight as well as diffuse light from the sun and outputting and concentrating the light like a funnel for reception at collimator 615 in a structure comprising brackets 645 for holding a collimator/separator/PV cells assembly seen in FIG. 6 only as collimator 615. As can be seen from FIG. 6, the domed Fresnel lens comprises a circular domed portion and a flat portion for focusing received light on collimator 615.

FIG. 7 shows in side view the brackets 645 and the domed Fresnel lens 620 with electrical conductors coming from the bottom of an assembly for generating electricity (not shown) comprising the collimator, spectral separator (hot or cold), a UV/visible PV cell below and reflected IR is received by a IR p/n junction cell.

FIG. 8 shows the assembly of a collimator 615, a spectral separator such as a cold mirror 840 for reflecting infrared energy to IR detector 870 seen as a first rectangular chip and a UV/visible detector or PV cell 850. The entire assembly is preferably provided with a heat sink 885 for alleviating heat build-up and protecting the chips from damage.

FIG. 9 shows a side cut-away view of the assembly of FIG. 8 with the collimator 615 cut in half exposed at the top and with spectral separator 840 reflecting infrared to PV p/n junction 870 and UV/visible to a UV/visible PV multi junction cell only visible because of a bolt for fixing the cell to the assembly. Again, the assembly is shown having a heat sink 885.

FIG. 10 exemplifies the reception at a UV/visible PV cell that is 10 mm by 10 mm such that the combination of the domed Fresnel lens, the collimator, the spectral separator (for example, a cold mirror) provides an even uniformity of irradiance within a 10 mm diameter circle at best focus. Because of the combination, multiplication magnitudes on the order of one to two thousand power are achieved and because of the dark regions, the integrated circuit assembly of the PV cell is left undisturbed by damaging heat.

FIG. 11 provides a top view of an aluminum monoblock assembly with the collimator and spectral separator removed. What is left are the heat sink 885, the UV/visible PV cell 850 and the IR p/n junction cell 870 showing electrical and heat conduction.

FIG. 12 shows an assembly of four such electricity generators with their respective dome-shaped Fresnel lens 620-1 through 620-4 at the top.

FIG. 13 shows dual axis tracking where a motor may track the sun from sunrise to sunset and a second motor may operate the North/South axis for tilting the structure of four cells to mtch the changing seasons and height of the sun in the sky.

FIG. 14 shows a graph of angle of incidence (AOI) measured against power on a detector such as a UV/visible detector for a domed Fresnel lens versus a conventional flat Fresnel lens, the graph showing a great increase in power over an AOI of zero to 0.2 degrees.

FIG. 15 shows the geometry of dimensions between lenses, cold mirrors and detectors where A is the distance from the Fresnel lens to the detector (in the case of a domed lens, the distance from the maximum sag to the detector, B is the distance from the vertex of a custom negative lens to a detector and dimension C is the midpoint of the cold mirror (spectral separator) to the detector.

### DESCRIPTION OF ILLUSTRATIVE EMBODIMENTS

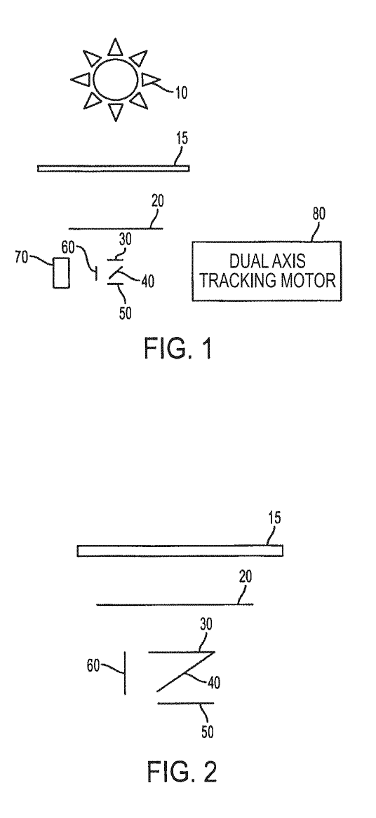

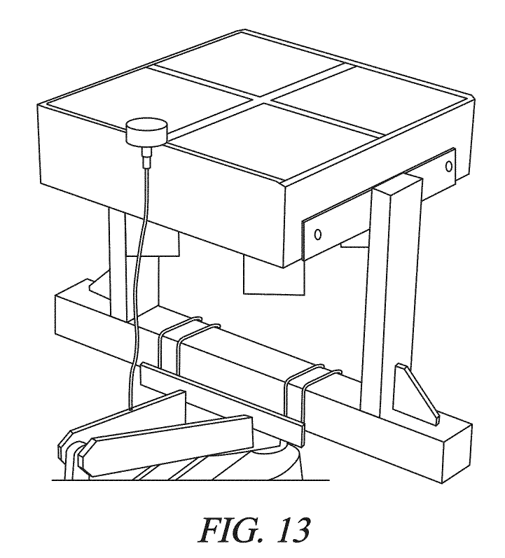

Similar reference characters will be used with reference to FIGS. 1-14 to represent similar elements. Referring to an example reference numeral XYY, X may represent the figure number where the component first appears and YY the two digit reference numeral for a similar earlier described component. An embodiment of a high efficiency hybrid solar concentrator may be described by way of introduction to what may be referred to as the five C's: capture, concentrate, collimate and constructively convert. First, we will discuss capture which has as an object the task of both capturing diffuse light and solar origin light. In connection with one embodiment of the present invention, the function of capture is best performed by a circular Fresnel lens 520 laid on a flat Fresnel lens surface. The high power solar concentrator may use this specially shaped Fresnel lens to obtain concentration on the order of one thousand suns or one thousand power concentration. The Fresnel lens may be converging and bends incident light beams to converge on a collimator. A spectral separator follows, for example, at a forty-five degree angle to direct IR in one direction to an IR detector and pass UV/visible light to a UV/visible light detector so that the IR does not disrupt the collection of UV/visible. The present system preferably uses dual axis tracking of the sun as it moves across the sky to provide up to 40% higher electricity generation than fixed tilt ground mounted systems. Dual axis tracking typically involves the use of a first system for daily sunrise to sunset tracking and a second system for compensating for the height in the sky of the sun between winter and summer by tilting a solar panel. In a subsequent discussion of FIG. 13, dual axis tracking will be discussed further.

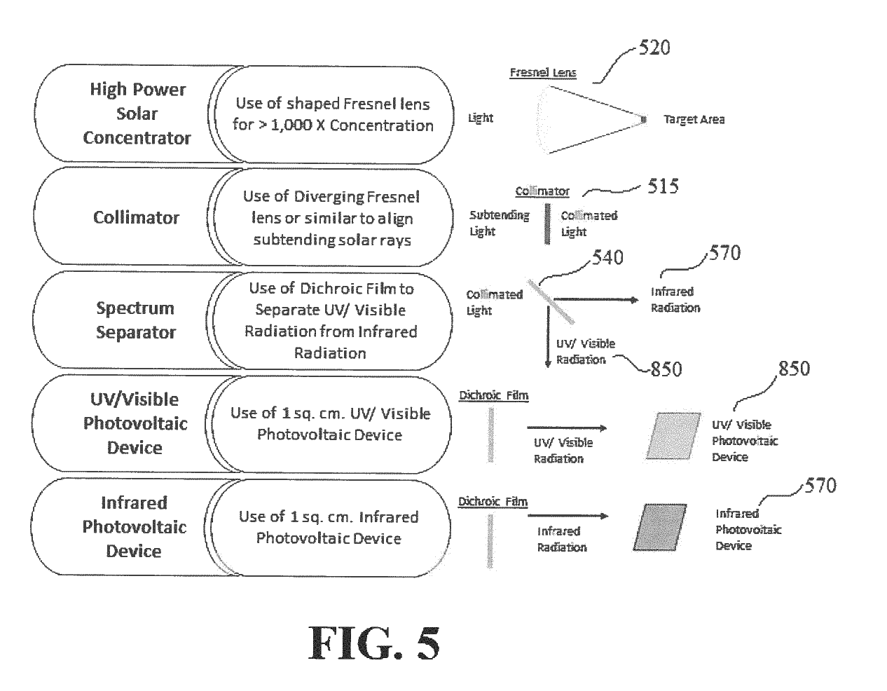

The second C stands for collimator 15, 515 which may use a diverging Fresnel lens or similar lens to straighten subtending solar rays and so collect diffuse light. As shown in FIG. 5, subtending light is transformed into collimated light by collimator 15, 515. In more plain language, the collimator may make crooked light straight for passing to a spectrum separator. The collimator assists in controlling the size or intensity of the light beam hitting each solar PV integrated circuit. Lack of control of the light, on the other hand, can cause the light to unintentionally reach parts of each integrated circuit or solar circuit card assembly. Over time, the concentrated light may diminish the production capability of the chip resulting in significant power losses. The collimator also may ensure that light is cast uniformly on the solar detector chips of two types (infrared and UV/visible). If the light is not collimated, the lack of uniformity in distribution can cause hot spots and/or structural moieties in the semiconductor.

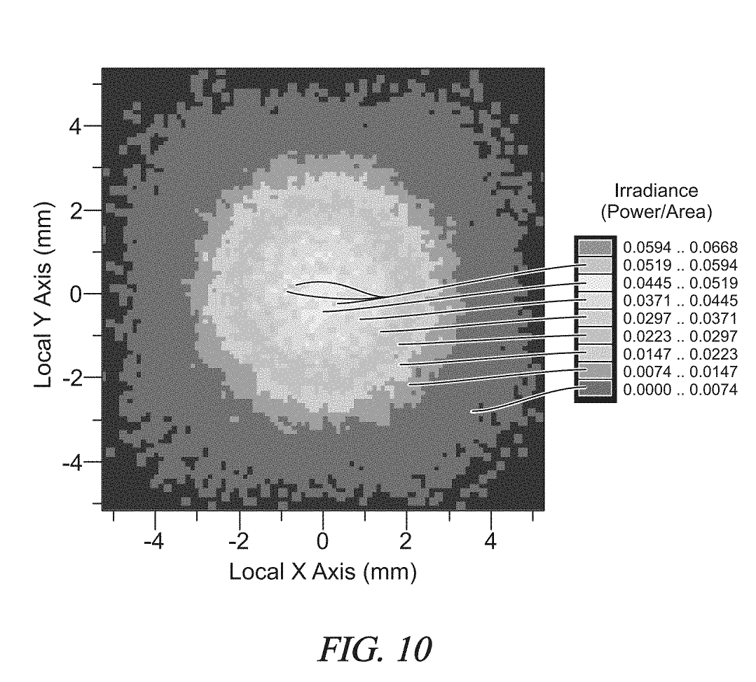

A spectrum separator may be a cold (or hot) mirror having a dichroic film. In one embodiment, UV and visible solar radiation is separated from infrared solar energy. The UV/visible light energy is passed to a UV/visible photovoltaic device 850 which may be ten millimeters in diameter (circular) or, in another example, ten millimeters square or comprise one square centimeter, approximately, for ideally receiving an even uniformity of both bandwidth across the UV/visible spectra and intensity as will be discussed, for example, with reference to FIG. 10.

On the other hand, the spectrum separator may comprise a dichroic film for passing infrared radiation to an infrared photovoltaic cell 570 of similar size to that of the UV/visible PV cell or ten millimeters by ten millimeters (one centimeter in diameter if circular or one centimeter square if square). The concentrated light is split into UV/visible light and infrared radiation. The UV/visible light is directed to a double junction PV cell or integrated circuit assembly which may convert fifty-three percent of the UV/visible light into electricity. The infrared radiation may be directed to a p/n junction cell which may convert approximately thirty percent of infrared radiation into electricity. Conventional PV and concentrated PV (CPV) efficiency is reduced by the thermal effects of infrared photons. Thus, infrared radiation reduces efficiency by increasing the temperature of the cell which in turn reduces effective conduction of electrons thus reducing efficiency by ten to twenty-five percent on hot days. As a result of the five C's approach, the embodiments described herein may operate at a concentration ratio of approximately one thousand five hundred suns (or one thousand five hundred magnification), or even two thousand suns and generate electricity (using both infrared and UV/visible cells) at an efficiency of approximately forty percent compared with the state-of-the art eighteen percent.

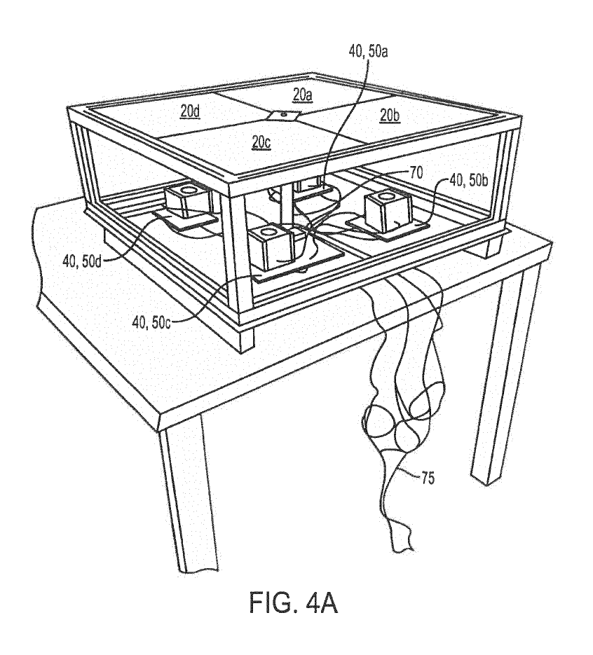

FIG. 1 provides an overall system diagram showing a first embodiment of a radiant energy concentrator system including a spectral separator. Electromagnetic radiation 10, for example, radiant energy from the sun may transmit light onto a collimator 15 first or directly on to a Fresnel lens 20. Collimator 15 collects and multiplies energy incident on it by a predetermined factor. By electromagnetic radiation 10, for example, radiant energy from the sun is used herein to comprise polychromatic visible light, infrared, ultraviolet and all other energy received at the earth's surface from the sun either directly or by diffusion. A suitable collimator 15, 515, for example, may be one obtained from Remote Light Inc. of Colorado, which may multiply incident radiation by a factor of up to ten or more (as well as straighten crooked light, for example, diffuse light from around the collimator as received from the much larger Fresnel lens. In other words, in alternative embodiments, collimator 15, 515 may collect, receive and multiply radiant energy from, for example, sun source 10, (or alternatively, Fresnel lens 20 may first receive radiant energy from sun source 10), as will be explained further with reference to FIG. 3. Each of the collimator 15, 515 and Fresnel lens devices may be a multiplier and a capturer of incident solar direct or diffuse energy. If the Fresnel lens 20 receives radiant energy from sun source (direct or diffuse), it can multiply incident radiation by a factor of up to one thousand or more.

The collimator 15, according to FIGS. 1, 2 and 3 may multiply the received electromagnetic radiation 10 by a predetermined factor. The collimator 15 acts as a funnel or light pipe for capturing light received from various directions including reflected light from sunlight bouncing off a building. According to FIGS. 1, 2 and 3, collimator 15 collects and concentrates radiant energy for reception at Fresnel lens 20, for example, on the order of a factor of up to one hundred times or more. The approximate distance between collimator 15 and Fresnel lens 20 is on the order of two to five centimeters in one embodiment, depending on the collimator 15 and Fresnel lens characteristics and parameters.

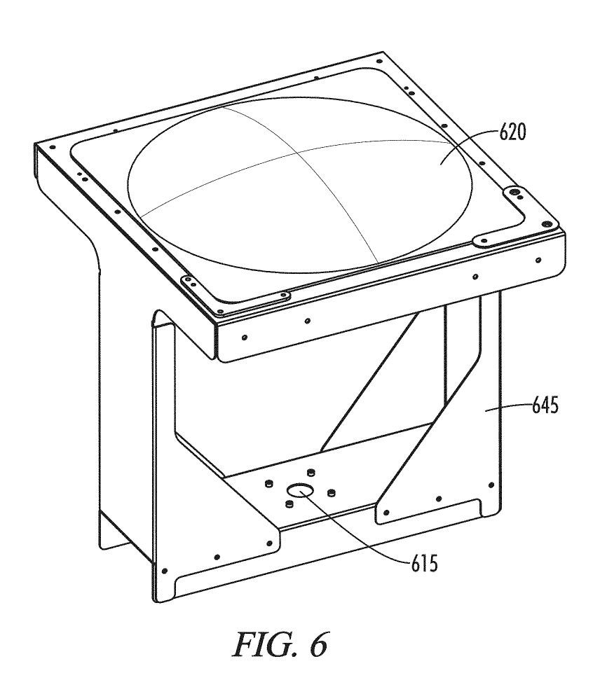

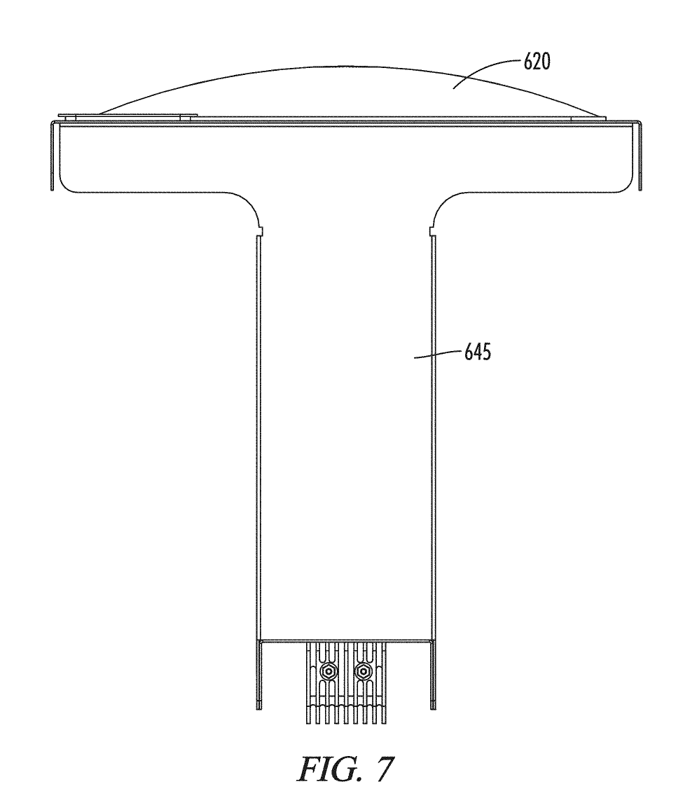

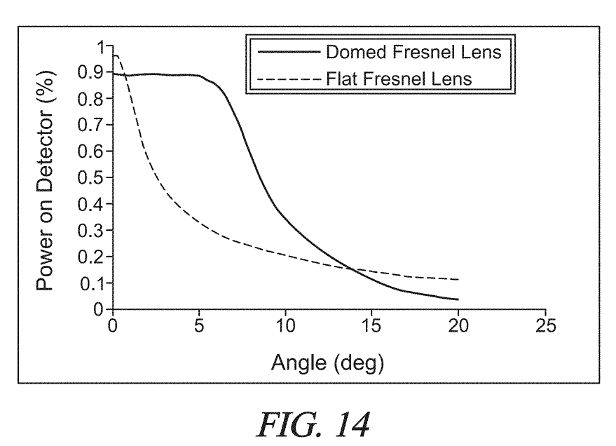

Furthermore, for example, a converging Fresnel lens 20 may multiply the electromagnetic radiation it receives directly from the sun source one thousand times or from the collimator 15 by a further predetermined factor. In one example, if collimator 15 multiplies by up to ten or more and converging Fresnel lens 20 by up to one hundred or more then, incident radiant energy is multiplied by a total factor of up to one thousand or more. In an alternative embodiment, the concentrating Fresnel lens 20 may be a shaped Fresnel lens; (see the converging dome-shaped lens of FIGS. 6 and 7) having an approximately which concentrates both direct and indirect light onto a collimator 515 (or a diverging Fresnel lens 30). A dome-shaped lens combined with a square flat lens of approximately 400 mm by 400 mm and the circular dome having a circular footprint having a diameter in a range from 250 mm to 300 mm with 283 mm a preferred value, clearly outperforms a conventional flat converging Fresnel lens by laboratory testing as seen in the graph of FIG. 14 showing power of detector versus angle of incidence or degree by a factor of two and the detector is moved to a position of best focus where a ninety percent power on detector is measured between 0° and eight degrees AOI.

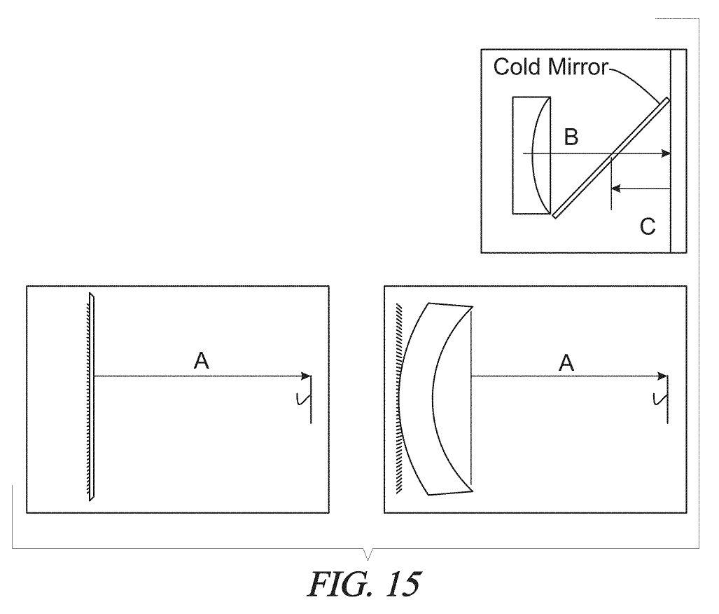

The domed Fresnel lens may be 400 mm×400 mm×3 millimeters and be manufactured of Polymethyl Methacrylate, a form of plastic. A cold mirror at either 35 mm×35 mm×3.3 mm or 25×25×3.3 mm may be constructed of borofloat glass from Schott AG of Mainz, Germany, with a dichroic film coating to reflect a preferred band, for example, IR and pass UV/visible. A custom negative lens may be matched with a domed Fresnel lens and a cold mirror at 35×35 millimeters and dimension A from the Fresnel lens to the detector is 419.5. Dimension B is the distance from the vertex of the custom negative lens to the detector at 39 millimeters and dimension C may be the midpoint between the cold mirror and the detector or sixteen millimeters per FIG. 15.

A conventional flat lens has been compared with a dome-shaped lens on a flat Fresnel lens surface and a twenty-five millimeters by twenty-five millimeters cold mirror and with a thirty-five millimeters by thirty-five millimeters cold mirror. With a 35×35 mm cold mirror, efficiency of energy conversion was greatly improved with a 10 mm×10 mm PV UV/visible detector. The hybrid solar concentrator provides high efficiency, low failure rate solar energy conversion in two separate solar bands, IR and UV/visible.

When a Fresnel lens is used as a concentrator, due to the light focusing characteristic of the Fresnel lens, a Fresnel lens is desirably used in conjunction with a motor system 80 or a plurality of light reflectors, not shown, for collecting and delivering the light to Fresnel lens 20 so that it may be further delivered without loss of radiant energy to system 30, 40, 50, 60, 70. The converging Fresnel lens 20, for example, may transmit light it receives onto a diverging Fresnel lens 30.

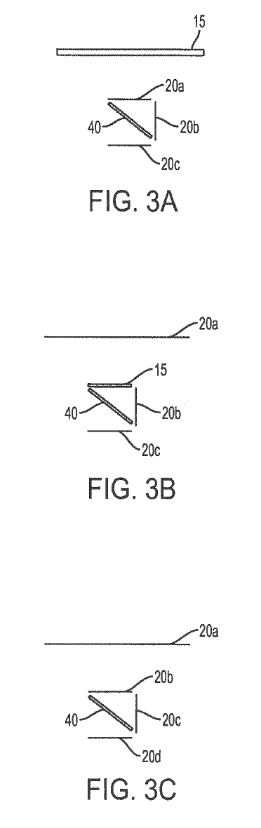

Converging Fresnel lens 20 and all elements shown below the Fresnel lens 20 in FIGS. 1 and 2 may be moved as the sun moves across the sky in the various seasons of the year (shorter or longer daylight hours) via a dual axis tracking motor system 80 controlled according to a sun calendar. A processor and associated software for motor control are not shown but may be used to program the motor system 80, for example, using GPS to identify the coordinates of a system according to the present invention to be installed. The motor system 80, in one embodiment, may be more conveniently used if the converging Fresnel lens 20 is used without a collimator 10. A similar motor system 80 is known, for example, from the field of telecommunications transmission and reception, for example, satellite tracking motor control systems with a difference being that the present system 80 may track the travel of the sun 10 or other source of electromagnetic radiation, if it is a moving source, for example, tracking the sun as it travels across the sky; (see FIG. 13).

As the light exits the diverging Fresnel lens 30, the light may be further collimated by a collimator not shown in FIG. 1 or 2, but see FIG. 3B. Visible and invisible light (for example, ultraviolet) exiting the Fresnel lens 30 of FIG. 1 or 2 may be transmitted through a spectrum separator, for example, a dichroic lens 40 and onto a solar photovoltaic cell 50 which produces electrical energy directly. The depicted spectrum separator 40 is shown at an angle of approximately 45°. In alternative embodiments, the angle may be between 20° and 80° depending on, for example, the desired location of a receiver such as a photovoltaic cell 50 or electrical or other energy accumulator 70 (for example, for accumulating heat energy). Accumulator 70 may, in one embodiment, comprise a steam or Stirling engine available from Edmund Scientific for generating an expanding liquid or gas. In another embodiment, accumulator 70 may be a conventional heat accumulator known in the art for receiving and accumulating infrared energy or may comprise a gallium antimonide (GaSb) p/n junction photovoltaic device doped with Zn and Te to convert infrared radiation to electricity at up to 30% conversion levels. Gallium arsenide may also be used in an alternative embodiment.

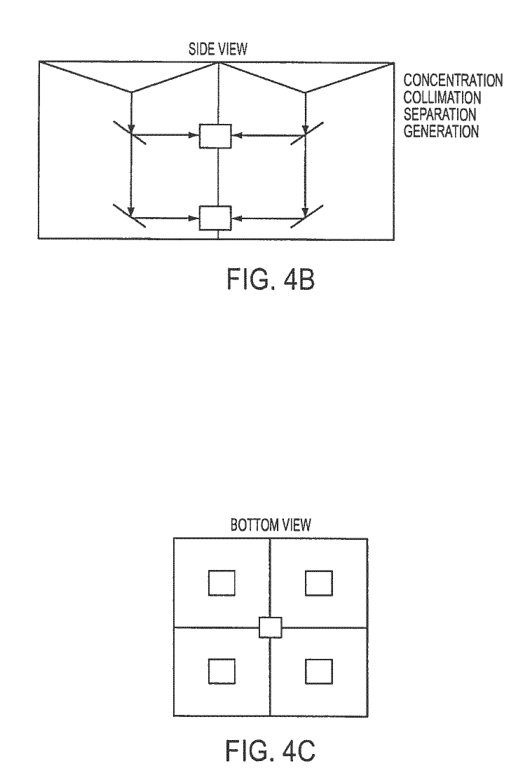

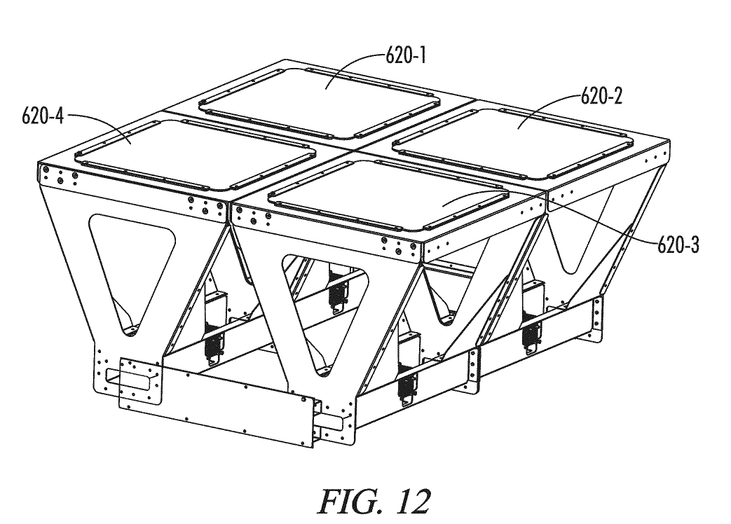

A plurality of stacked hot or cool spectrum separators, for example, dichroic lenses, 40 may receive light and transmit or reflect the light at different spectral bands to different photovoltaic cells 50 or accumulators 70 operable at different spectral bands at different receiving locations. On the other hand, infrared light may be reflected from the dichroic lens 40 either onto an accumulator 70, a further collimator, not shown, or is focused through an IR Fresnel lens 60 onto an accumulator 70. Moreover, in one embodiment, an array of 2×2 or other array of Fresnel lenses (FIG. 4, FIG. 12 or FIG. 13) and spectrum separators may direct infrared energy to a single, central accumulator 70. Thus, the depicted IR Fresnel lens 60 may be optional or useful to increase the overall electrical efficiency or for mechanical or chemical energy generation. The accumulator 70 then may, for example, either distill liquid, expand a working fluid, produce mechanical energy, generate thermal energy, convert hazardous waste into fuel and/or generate electrical energy.

FIGS. 3(A) to (C) show a plurality of embodiments utilizing collimator 15 and Fresnel lenses 20 in various combinations with hot or cold spectral separators 40. For example, FIG. 3A shows an embodiment where collimator 15 multiplies and collects radiant energy and transmits received, collected radiant energy to Fresnel lens 20a which focuses the radiant energy on spectral separator 40 which may be hot or cold. If separator 40 is hot, it passes infrared energy to be focused by further Fresnel lens 20c on to an accumulator 70 not shown below. Separator 40 reflects visible light toward Fresnel lens 20b for delivery to a photovoltaic cell 50 not shown. If a cold separator is used, the infrared energy is reflected by separator 40 and reflected toward Fresnel lens 20b at the right for focusing on an accumulator 70, not shown, proximate the spectral separator. UV/visible light is passed by cold separator 40 to a Fresnel lens 20c to a photovoltaic cell 50 below the spectral separator (not shown).

FIG. 3B may be similarly explained to one of ordinary skill understanding that FIG. 3B comprises Fresnel lens 20a as a first multiplier for transmitting radiant energy it receives to collimator 15. Collimator 15 pipes the received radiant energy to hot or cold separator 40, for example, a suitable dichroic filter. If separator 40 is hot, it passes infrared energy to be focused by further Fresnel lens 20c on to an accumulator 70 not shown below. Separator 40 reflects visible light toward Fresnel lens 20b for delivery to a photovoltaic cell 50 not shown. If cold, the infrared energy is reflected by separator 40 and reflected toward Fresnel lens 20b at the right for focusing on an accumulator 70 not shown. Visible light is passed by cold separator 40 to a Fresnel lens 20c to a photovoltaic cell 50 below (not shown).

FIG. 3C may be similarly explained to one of ordinary skill understanding that FIG. 3C comprises first Fresnel lens 20a as a first multiplier for transmitting radiant energy it receives to second Fresnel lens 20b as a second multiplier. Second Fresnel lens 20b transmits the received radiant energy to hot or cold separator 40, for example, a suitable dichroic filter. If separator 40 is hot, it passes infrared energy to be focused by further Fresnel lens 20d on to an accumulator 70 not shown below. Separator 40 reflects visible light toward Fresnel lens 20c for delivery to a photovoltaic cell 50 not shown. If cold, the infrared energy is reflected by separator 40 and reflected toward Fresnel lens 20c at the right for focusing on an accumulator 70 not shown. Visible light is passed by cold separator 40 to a Fresnel lens 20d to a photovoltaic cell 50 below (not shown).

FIG. 4(A) is a perspective view drawing showing a Fresnel lens system in the form of a two by two array for multiplying light and delivering the infrared portion of the spectrum to a single accumulator 70 at the center of a system of a two by two array of separators 40. FIG. 4(B) provides a side view of the system of FIG. 4(A) showing the steps of concentration, collimation separation and energy generation (where the concentration and collimation steps may be reversed). FIG. 4(B) may show a photovoltaic cell as a white box and an energy accumulator as a black box where only the black box is seen in bottom view FIG. 4(C). By using a collimator 15 (not shown) to collect diffuse radiant energy for each Fresnel lens 20 of such a system as depicted in FIG. 4(A), the overall efficiency of conversion of incident radiant energy to, for example, electric energy may be increased from a typical 18% to an efficiency in excess of 40% and, in one embodiment, in excess of 60%. Converging Fresnel lenses 20a, 20b, 20c and 20d are shown receiving incident radiant energy and delivering and multiplying received energy to a system as seen in FIG. 2 comprising, for example, at least a spectrum separator 40 for reflecting IR and a photovoltaic cell 50 for generating electricity. An accumulator 70, shaped as a central cylindrical column, receives infrared heat energy which may be converted to chemical or electrical or mechanical energy. Each photovoltaic cell has output leads 75 which may be collected and passed through an aperture in the planar base surface of the system.

One or a plurality of embodiments of a system such as may be seen in FIG. 4(A) through FIG. 4(C) may be mounted, for example, on the roof of a manufacturing facility with hazardous waste as an output. The visible spectrum may be used for generating electricity for running the plant and the infrared energy for use as heat and chemical energy for treating the effluent waste output and converting the waste to fuel, for example, a hydrocarbon fuel.

Now, a model of an embodiment of a high efficiency hybrid solar concentrator will be discussed with reference to FIGS. 6 through 11. The structure described simultaneous manages both heat and optics to achieve the most efficient conversion. Collimation is used to uniformly apply both intensity and color to reduce hot spots and structural moieties. Also, spectral separation reduces heat generation from UV/visible and infrared on both photovoltaic devices, thus reducing the heat load required to manage. Lastly, use of the Al (Aluminum) monoblock with heat fins and conventional heat dissipation easily radiates any excess heat from the system which produces a high efficiency, low cost solar technology. For example, the Fresnel lens system may be 40 centimeters by 40 centimeters while the IR or UV/visible chip size is one cm². This results in a multiplication of one thousand six hundred between the lens system area and the chips' area, and as per FIG. 10, a uniform distribution and high efficiency of solar energy conversion to electrical energy leaving little heat energy to dissipate by the conventional means.

FIG. 6 shows in perspective view a domed Fresnel lens 620 for capturing direct sunlight as well as diffuse light from the sun and outputting and concentrating the light like a funnel for reception at collimator 615 in a structure comprising brackets 645 for holding a collimator/separator/PV cells assembly seen in FIG. 6 only as collimator 615. As can be seen from FIG. 6, the domed Fresnel lens 620 comprises a circular domed portion and a flat square portion for focusing received light on collimator 615. The lens may be constructed of Polymethyl Methacrylate, be 400 mm by 400 mm by 3 mm where a flat Fresnel lens portion may have a 0.5 mm pitch. The range in size may be between 200 mm×200 mm and 500 mm×500 mm. A typical range of ratio then is from 400 to 2500×. Given that in one embodiment 400 mm is forty centimeters, the overall area is 40×40 or 1600 cm². Also, given that the size of PV cells is one cm², the overall size of the Fresnel lens system is one thousand six hundred times the size of either a UV/visible multijunction chip or a IR p/n junction chip, both with high electrical coversion and little residual heat and so high concentration ratios are achieved on the order of one to two thousand (compared with the prior art at 40×).

FIG. 7 shows in side view the brackets 645 and the domed Fresnel lens 620 with electrical conductors coming from the bottom of an assembly for generating electricity (not shown) comprising the collimator, spectral separator (preferably cold), a UV/visible PV cell below and reflected IR is received by a IR p/n junction cell to the side.

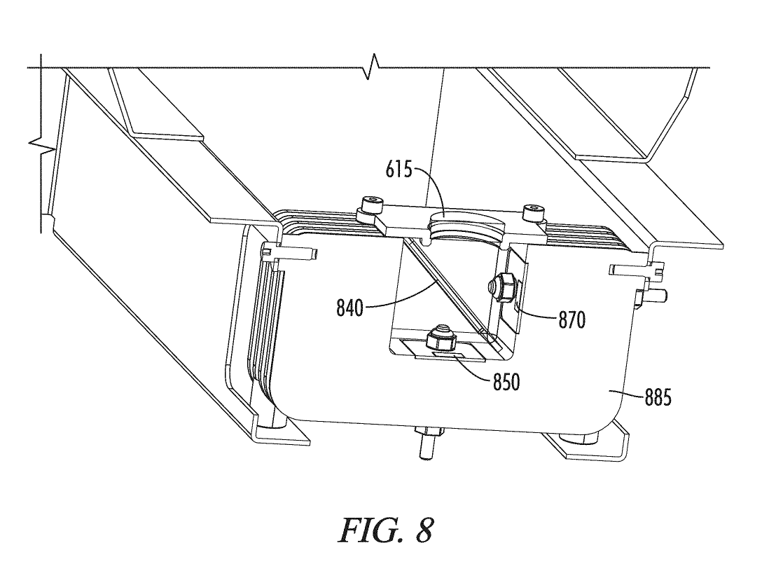

FIG. 8 shows the assembly of a collimator 615, a spectral separator such as a cold mirror 840 for reflecting infrared energy to IR detector 870 seen as a first rectangular chip and a UV/visible detector or PV cell 850 below the spectral separator (cold mirror). The entire assembly is preferably provided with heat management. In particular, due to the high conversion of solar energy to electricity, there is little residual heat energy to disperse. Known heat dissipating techniques may be used to protect the assembly from reach such a temperature as 200° C. So, for example, a heat sink 885 as well as other known measures are taken for alleviating heat build-up and protecting the chips and circuit assemblies from damage. As already explained, there is a uniform distribution of the solar energy on either cell and the energy does not reach to circuit assembly components. Moreover, the IR energy is removed from the incident energy and converted separately to electricity from the remaining UV/visible energy.

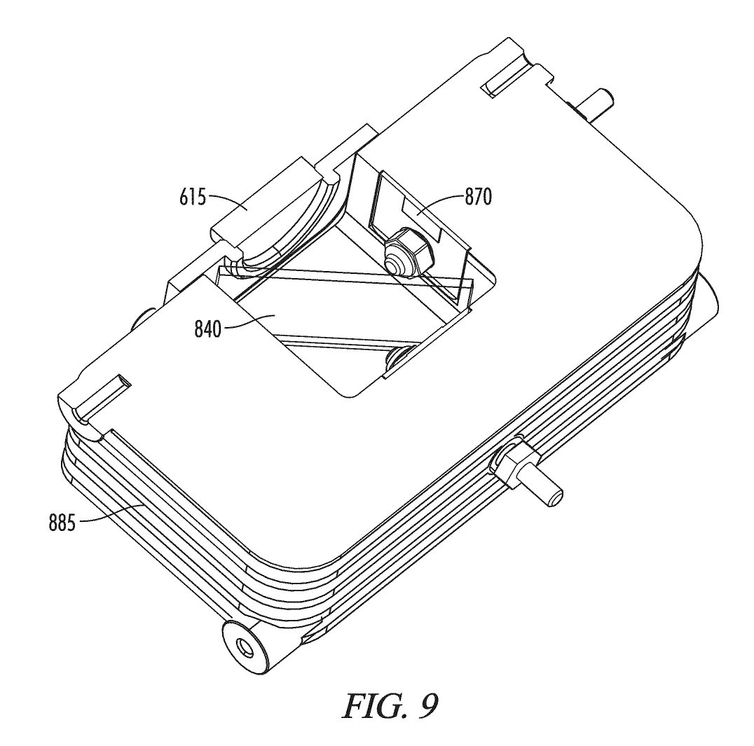

FIG. 9 shows a side cut-away view of the assembly of FIG. 8 with the collimator 615 cut in half exposed at the top and with spectral separator 840 reflecting infrared to PV p/n junction 870 and UV/visible to a UV/visible PV cell only visible because of a bolt for fixing the cell to the assembly. Again, the assembly is shown having conventional heat dissipation such as including a heat sink 885.

FIG. 10 exemplifies the reception at a UV/visible PV cell that is 10 mm by 10 mm such that the combination of the domed Fresnel lens, the collimator, the spectral separator (for example, a cold mirror) provides an even uniformity of irradiance within a 10 mm diameter circle at best focus. Because of the combination, multiplication magnitudes on the order of one to two thousand power are achieved and because of the dark regions, the integrated circuit assembly of the PV cell is left undisturbed by damaging heat.

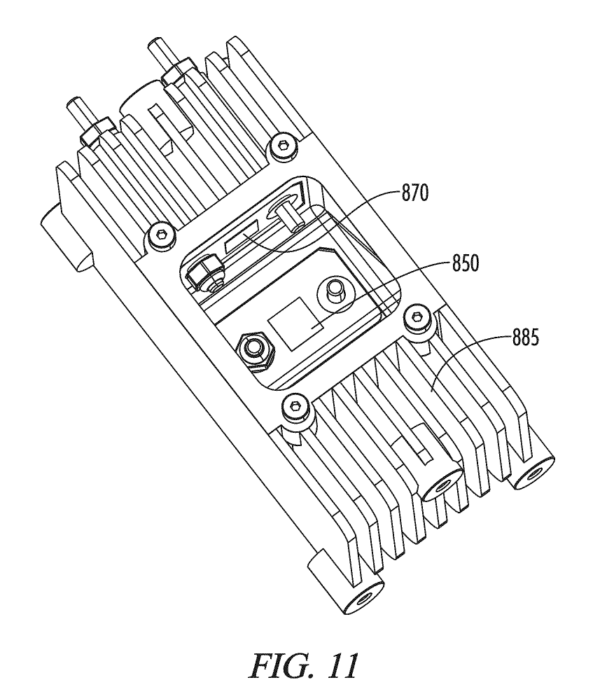

FIG. 11 provides a top view of an aluminum monoblock assembly with the collimator and spectral separator removed. What is left are the conventional heat dissipation represented by heat sink 885, the UV/visible PV cell 850 and the IR p/n junction cell 870 showing electricity generation at over 50% efficiency and heat conduction.

FIG. 12 shows an assembly of four such electricity generators with their respective dome-shaped Fresnel lens 620-1 through 620-4 at the top. The two by two array is preferred for forming a structure for following the sun as is seen by the embodiment of FIG. 13.

FIG. 13 shows dual axis tracking where a motor may track the sun from sunrise to sunset and a second motor may operate the North/South axis for tilting the structure of four cells to match the changing seasons and height of the sun in the sky.

FIG. 14 shows a graph of angle of incidence (AOI) measured against power on a detector such as a UV/visible detector for a domed Fresnel lens versus a conventional flat Fresnel lens, the graph showing a great increase in power over an AOI of zero to 0.2 degrees.

FIG. 15 shows the geometry of dimensions between lenses, cold mirrors and detectors where A is the distance from the Fresnel lens to the detector (in the case of a domed lens, the distance from the maximum sag to the detector, B is the distance from the vertex of a custom negative lens to a detector and dimension C is the midpoint of the cold mirror (spectral separator) to the detector. A custom negative lens is used and preferred over negative lens NT45922, a domed Fresnel lens is used with the dimensions given above and a cold mirror is used for reflecting IR and passing UV/visible. The domed converging Fresnel lens has a maximum transmission of approximately 89%. A preferred value of A is 419.5 mm. A preferred value of B is 30 mm, and a preferred value of C is 16 mm. Irradiance is defined as power divided by area. Including a transmission loss T associated with optics, irradiance E is equal to TP/A (where P is power and A is area). The maximum irradiance of the preferred embodiment is 0.0160 (with a 35 mm×35 mm cold mirror) and power is at 0.708.

All patents and articles referenced herein should be deemed to be incorporated herein by reference in their entirety as to their entire subject matter. One of ordinary skill in the art should only deem the several embodiments of a solar concentrator and conversion apparatus and method described above to be limited by the scope of the claims which follow.

What we claim is:

1. Apparatus for obtaining radiant energy from a polychromatic radiant energy source, the apparatus comprising:
a flat, configurable concentrating lens for concentrating the radiant energy to a multiple of incident radiant energy, the multiple being a factor of up to approximately ten times or more;
a converging domed Fresnel lens mounted on the flat, configurable concentrating lens for further concentrating the radiant energy to a combined multiplication factor being approximately one thousand times or more, the flat and domed Fresnel lens forming a converging Fresnel lens system;
a spectral separator at an angle between 20° and 80° to the concentrated light for separating the concentrated radiant energy into spectral bands, the spectral separator being approximately ten times smaller in surface area than the Fresnel lens system;
a photovoltaic device for receiving a first spectral band comprising visible light passed by the spectral separator and converting the received first spectral UV/visible band into electricity; and
a second device for receiving a second spectral band comprising infrared electromagnetic energy reflected by the spectral separator and for utilizing at least one of converted electrical energy and infrared heat energy received in said infrared electromagnetic energy.

2. The apparatus of claim 1 wherein the ratio between the sizes of the flat lens in combination with the converging domed Fresnel lens and a detector area of either the first or the second device ranges from one thousand to twenty-five hundred times.

3. The apparatus of claim 1 wherein the concentrator comprises a collimator and a diverging Fresnel lens after the collimator.

4. The apparatus of claim 1 wherein the collimator concentrator and Fresnel lens system comprise a converging Fresnel lens for concentrating the radiant energy to a multiple of incident energy of approximately one thousand times and an energy efficiency in excess of 36% and up to 60% or more between the incident energy and useful energy output.

5. The apparatus of claim 1 wherein the collimator concentrator and Fresnel lens system comprise a shaped converging Fresnel lens having a circular footprint on a flat surface to capture diffused incident light providing up to 15% or greater light capturing capability.

6. The apparatus of claim 1 wherein the spectral separator comprises a dichroic lens and the spectral bands comprise a first spectral band comprising ultraviolet and visible light bands, and a second spectral band comprising infrared electromagnetic energy of wavelengths of 700 nm and up to 1000 nm.

7. The apparatus of claim 6 wherein the dichroic lens comprises a plurality of dichroic lenses operable at different bands in the combined visible and ultraviolet spectrum.

8. The apparatus of claim 1 further comprising a dual axis tracking motor system for moving said apparatus to follow a direct or diffuse source of solar electromagnetic radiation.

9. The apparatus of claim 4 further comprising an infrared Fresnel lens.

10. The apparatus of claim 1 wherein the second device includes a heat accumulator.

11. The apparatus of claim 1 wherein the second device includes a gallium antimonide (GaSb) photovoltaic device, responsive to the spectral separator, to convert the second spectral band comprised of infrared electromagnetic energy into electricity.

12. Apparatus for obtaining radiant energy from a polychromatic radiant energy source, the apparatus comprising:
a collimator concentrator for concentrating the radiant energy to a multiple of incident radiant energy, the multiple being a factor of up to approximately ten or more;
a Fresnel lens having a dome shape on a flat surface for concentrating radiant energy to a multiple of incident radiant energy to a combined multiplication factor of up to two thousand times;
a spectral separator for separating the concentrated radiant energy into spectral bands, the spectral separator comprising a transmitter of one spectral band and a reflector of the second spectral band;
a first photovoltaic device, responsive to the spectral separator, for receiving a first spectral band comprising visible and ultraviolet light and converting the received first spectral band into electricity; and
a second photovoltaic device for receiving a second spectral band comprising infrared electromagnetic energy and for utilizing at least heat energy received in said infrared electromagnetic energy.

13. The apparatus of claim 12 further comprising a converging Fresnel lens for further concentrating the radiant energy to a factor up to two thousand times the Fresnel lens having a square shape and being a multiple of forty times the size of the first and second devices.

14. The apparatus of claim 12 further wherein the spectral separator comprises a hot dichroic lens.

15. The apparatus of claim 12 wherein the spectral separator comprises a cold dichroic lens.

16. The apparatus of claim 12 comprising an array of Fresnel lens, collimator and spectral separators focusing energy at a central accumulator.

17. A method for converting radiant solar energy to electric energy and to another form of energy comprising:
a collimator concentrator for concentrating the electromagnetic, radiant energy to a multiple of incident electromagnetic radiant energy, the multiple being a factor of up to approximately ten times or more;
a Fresnel lens system for concentrating the electromagnetic, radiant energy to a multiple of incident electromagnetic radiant energy, the combined multiplication factor of the collimator concentrator and the Fresnel lens system being approximately up to one thousand times or more;
a spectral separator for separating the concentrated radiant energy into first and second spectral bands, the first spectral band comprising the visible light spectrum and the second spectral band comprising the infrared electromagnetic, radiant energy band;
a first photovoltaic device, responsive to the spectral separator, for receiving the first spectral band and converting the received first spectral band into electricity; and
a second photovoltaic device, responsive to the spectral separator, for receiving the second spectral band and for utilizing energy received in said second spectral band of said infrared electromagnetic, radiant energy for a different application than for conversion to electricity.

18. The method of claim 17 wherein the other form of energy is one of mechanical, chemical, electrical and thermal energy where electrical energy is provided by the first photovoltaic device and the second photovoltaic device with an overall light to electricity conversion efficiency in excess of fifty percent.
